(19) United States
(12) Patent Application Publication
(10) Pub. No.: US 2024/0421795 A1
(43) Pub. Date: Dec. 19, 2024

(54) ELECTRONIC MODULE

(71) Applicant: Murata Manufacturing Co., Ltd., Kyoto-fu (JP)

(72) Inventors: Mari SAJI, Nagaokakyo-shi (JP); Takashi YAMANE, Nagaokakyo-shi (JP)

(73) Assignee: Murata Manufacturing Co., Ltd., Kyoto-fu (JP)

(21) Appl. No.: 18/813,289

(22) Filed: Aug. 23, 2024

Related U.S. Application Data
(63) Continuation of application No. PCT/JP2023/006714, filed on Feb. 24, 2023.

(30) Foreign Application Priority Data
Mar. 1, 2022 (JP) 2022-030976

(51) Int. Cl. H03H 9/05; H03H 3/08; H03H 9/08; H03H 9/10; H03H 9/25

(52) U.S. Cl. CPC H03H 9/0542; H03H 3/08; H03H 9/059; H03H 9/08; H03H 9/1085; H03H 9/25

(57) ABSTRACT

A semiconductor element having a structure in which a wiring layer, an element formation layer, and a first insulating layer are stacked is mounted on a first surface of a module substrate in a state where the wiring layer faces the module substrate. The electronic component is mounted on the first surface of the module substrate. A resin layer is on the first surface of the module substrate. First and second recessed portions are in the resin layer, a semiconductor element is in the first recessed portion, and the electronic component is in the second recessed portion. When the first surface is set as a height reference, an upper surface of the resin layer includes a region which is higher than or equal to heights of an upper surface of the semiconductor element and an upper surface of the electronic component, around the semiconductor element and the electronic component.

### CROSS-REFERENCE TO RELATED APPLICATIONS

This application claims benefit of priority to International Patent Application No. PCT/JP2023/006714, filed Feb. 24, 2023, and to Japanese Patent Application No. 2022-030976, filed Mar. 1, 2022, the entire contents of each are incorporated herein by reference.

### BACKGROUND

### Technical Field

The present disclosure relates to an electronic module.

### Background Art

A semiconductor device in which characteristics of semiconductor elements are improved by using a silicon on insulator (SOI) substrate is known as described, for example, in International Publication No. 2019/163580. In a communication module disclosed in International Publication No. 2019/163580, the semiconductor element is mounted on a module substrate and sealed by a sealing resin, and then the sealing resin is ground up to a rear surface of the semiconductor element. Thereafter, a silicon support substrate of the semiconductor element is removed by etching to expose a buried insulating layer of the SOI substrate. By removing the silicon support substrate, reduction of characteristics due to a resistance component of the silicon support substrate or a parasitic capacitance component caused by the silicon support substrate is suppressed.

### SUMMARY

A semiconductor device of the related art requires to perform sealing of one type of semiconductor element with a sealing resin, grinding of the sealing resin, and removal of a silicon support substrate by etching. Accordingly, it is difficult to reduce manufacturing costs. Therefore, the present disclosure provides an electronic module capable of reducing manufacturing costs.

According to one aspect of the present disclosure, there is provided an electronic module including a module substrate, a semiconductor element in which a wiring layer, an element formation layer, and a first insulating layer are stacked and which is mounted on a first surface of the module substrate in a state where the wiring layer faces the module substrate, an electronic component mounted on the first surface of the module substrate, and a resin layer disposed on the first surface of the module substrate. A first recessed portion and a second recessed portion are provided in the resin layer, the semiconductor element is accommodated in the first recessed portion, and the electronic component is accommodated in the second recessed portion. Also, when the first surface is set as a height reference, an upper surface of the resin layer includes a region, which is higher than or equal to heights of an upper surface of the semiconductor element and an upper surface of the electronic component, around the semiconductor element and the electronic component.

By mounting a semiconductor element and an electronic component other than the semiconductor element on a common module substrate, manufacturing costs can be reduced as compared with a configuration in which the semiconductor element and the electronic component are separately mounted.

### BRIEF DESCRIPTION OF THE DRAWINGS

FIG. 1A is a plan view of an electronic module according to a first embodiment, and

FIG. 1B is a cross-sectional view taken along an alternated long and short dash line 1B-1B of FIG. 1A;

FIG. 2A is a schematic cross-sectional view of an electronic component mounted on the electronic module according to the first embodiment, and FIG. 2B is a plan view illustrating an example of a pattern of an IDT electrode and a pair of reflectors;

FIG. 3 is a schematic cross-sectional view taken along an alternated long and short dash line 3-3 of FIG. 2A;

FIG. 4A to FIG. 4D are cross-sectional views of the electronic module according to the first embodiment in a middle process of manufacturing;

FIGS. 5A and 5B are cross-sectional views of an electronic component mounted on an electronic module according to a modification example of the first embodiment;

FIGS. 6A, 6B, and 6C are cross-sectional views of the electronic component mounted on the electronic module according to the modification example of the first embodiment;

FIG. 7 is a cross-sectional view of an electronic module according to a second embodiment;

FIG. 8 is a cross-sectional view of an electronic module according to a third embodiment;

FIG. 9 is a cross-sectional view of an electronic module according to a fourth embodiment;

FIG. 10 is a cross-sectional view of an electronic module according to a fifth embodiment;

FIG. 11 is a cross-sectional view of an electronic module according to a sixth embodiment;

FIG. 12 is a cross-sectional view of an electronic module according to a modification example of the sixth embodiment;

FIG. 13 is a cross-sectional view of an electronic module according to a seventh embodiment;

FIG. 14 is a cross-sectional view of an electronic module according to an eighth embodiment; and

FIG. 15 is a cross-sectional view of an electronic module according to a ninth embodiment.

### DETAILED DESCRIPTION

### First Embodiment

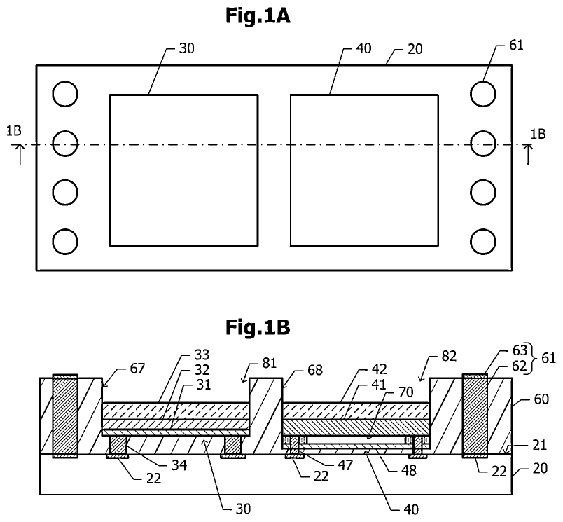

An electronic module according to a first embodiment will be described with reference to FIG. 1A to FIG. 4D.

FIG. 1A is a plan view of an electronic module according to the first embodiment, and FIG. 1B is a cross-sectional view taken along an alternated long and short dash line 1B-1B of FIG. 1A. A semiconductor element 30 and an electronic component 40 are mounted on a first surface 21 which is one surface of a module substrate 20. Further, a plurality of outer coupling terminals 61 for coupling to an outer circuit are disposed on the first surface 21 of the module substrate 20. A direction in which the first surface 21 faces is defined as an upper side. Each of the outer coupling terminals 61 includes a conductor column 62 that is erected on a land 22 of the module substrate 20 and a conductor layer 63 that covers an upper surface (a surface facing the same direction as the first surface 21) of the conductor column 62.

The semiconductor element 30 includes a stacked structure in which a first insulating layer 33, an element formation layer 32, and a wiring layer 31 are stacked from an upper side to a lower side, and a plurality of bumps 34 protruding from the wiring layer 31. The semiconductor element 30 is mounted on the module substrate 20 by coupling a plurality of bumps 34 to lands 22 of the module substrate 20. A plurality of active elements such as transistors and a plurality of passive elements such as a resistor and a capacitor are formed in the element formation layer 32. An integrated circuit is configured with the plurality of active elements, the passive elements, and a plurality of wires in the wiring layer 31. The integrated circuit is, for example, a low-noise amplifier that amplifies a high-frequency signal, a band selection switch that selects one filter from a plurality of filters provided for each frequency band, an antenna selection switch that selects one antenna from a plurality of antennas, and the like.

The first insulating layer 33 is located on a side opposite to the wiring layer 31 in a view from the element formation layer 32. The first insulating layer 33 is formed of an oxide (for example, a silicon oxide) of a constituent element (for example, silicon) of the element formation layer 32.

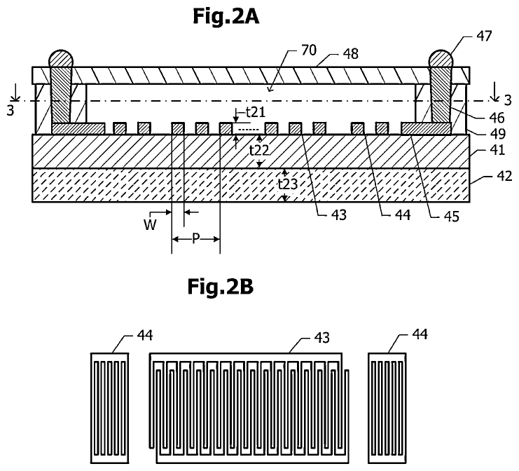

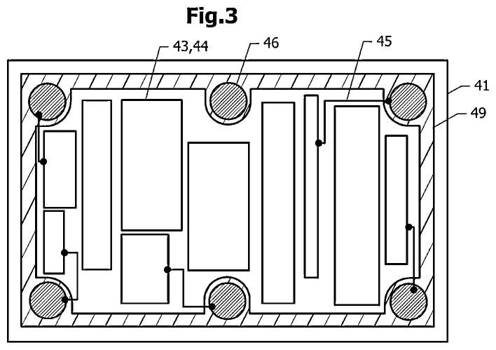

Next, a configuration of the electronic component 40 will be described with reference to FIG. 2A to FIG. 3.

FIG. 2A is a schematic cross-sectional view of the electronic component 40 mounted on the electronic module according to the first embodiment. In FIG. 2A, the electronic component 40 illustrated in FIG. 1B is displayed upside down. IDT electrodes 43, reflectors 44, and wires 45 are disposed on one surface of a piezoelectric layer 41 formed of a piezoelectric material such as LiTaO₃, and a second insulating layer 42 is disposed on the other surface. That is, when a direction from the module substrate 20 of FIG. 1B to the electronic component 40 thereof is defined as an upward direction, the electronic component 40 includes the second insulating layer 42 in an uppermost layer (a lowermost layer in FIG. 2A). A material or the like, which mainly includes, for example, silicon oxide, glass, silicon oxynitride, tantalum oxide, or a compound obtained by adding fluorine, carbon, or boron to the silicon oxide, is used for the second insulating layer 42. The second insulating layer 42 may be a single layer or may be a plurality of layers formed of different insulating materials.

A spacer layer 49 formed of an insulating material is disposed in a peripheral edge portion of a surface of the piezoelectric layer 41 on which the IDT electrode 43 is disposed. The spacer layer 49 surrounds a region, in which the IDT electrode 43 is disposed in a plan view, without interruption. A cover member 48 is disposed at a distance from the piezoelectric layer 41, and the cover member 48 is supported by the spacer layer 49. A closed cavity 70 is formed by the piezoelectric layer 41, the spacer layer 49, and the cover member 48.

A plurality of openings penetrating in a thickness direction are provided in the cover member 48 and the spacer layer 49. Through-electrodes 46 are respectively filled in the openings. The through-electrodes 46 are respectively coupled to the IDT electrodes 43 through the wires 45.

Solder bumps 47 are disposed on end surfaces of the through-electrodes 46 on the cover member 48 side. The electronic component 40 is mounted on the module substrate 20 by coupling the solder bumps 47 to the land 22 (FIG. 1B) of the module substrate 20.

A thickness of the piezoelectric layer 41 is denoted by t22, and a thickness of the second insulating layer 42 is denoted by t23. A thickness of the IDT electrode 43 is denoted by t21, a width of each of electrode fingers of the IDT electrodes 43 is denoted by W, and a period of the electrode finger is denoted by P. When a high-frequency signal is supplied to the IDT electrode 43, a surface acoustic wave is excited in the piezoelectric layer 41. A wavelength λ of the surface acoustic wave is equal to the period P of the electrode finger of the IDT electrode 43. For example, the number of pairs of the electrode fingers of the IDT electrodes 43 is about 200. The width W of each of the electrode fingers of the IDT electrodes 43 is ¼ of the period P, and the thickness t21 of the IDT electrode 43 is about 10% of the period P. The thickness t22 of the piezoelectric layer 41 and the thickness t23 of the second insulating layer 42 are 20% or more and 30% or less (i.e., from 20% to 30%) of the wavelength λ (that is, the period P) of the excited surface acoustic wave.

FIG. 2B is a plan view illustrating an example of a pattern of the IDT electrode 43 and a pair of reflectors 44. The IDT electrode 43 is composed of a pair of comb-tooth electrodes that are engaged with each other. The pair of reflectors 44 are disposed on both sides of the IDT electrode 43 in a direction in which the electrode fingers of the IDT electrodes 43 are disposed. The IDT electrode 43 and the reflector 44 are configured with a stacked metal film in which a plurality of metal layers are stacked, or a single-layer metal film.

The surface acoustic wave excited by a high-frequency signal supplied to the IDT electrode 43 propagates in a direction in which a plurality of electrode fingers are disposed and is reflected by the reflector 44. A one-port type acoustic wave resonator is configured by one IDT electrode 43 and a pair of reflectors 44.

FIG. 3 is a schematic cross-sectional views taken along an alternated long and short dash line 3-3 of FIG. 2A. In FIG. 3, a region where one IDT electrode 43 and a pair of reflectors 44 corresponding to the IDT electrode 43 are disposed is illustrated as a rectangle, and the wire 45 is schematically illustrated as a polygonal line. The spacer layer 49 of an annular shape is disposed slightly inside an outer peripheral line of the piezoelectric layer 41.

A plurality of IDT electrodes 43 are disposed in a region surrounded by the spacer layer 49. A pair of reflectors 44 are disposed for each IDT electrode 43. A plurality of the through-electrodes 46 are disposed to be included in the spacer layer 49 in a plan view. The through-electrodes 46 are respectively coupled to the IDT electrodes 43 through the wires 45. A ladder filter, a vertical coupling filter, a lattice type filter, a transversal type filter, and the like are configured by the plurality of IDT electrodes 43. The plurality of IDT electrodes 43 are also coupled to each other by other wires (not illustrated).

As illustrated in FIG. 1B, a resin layer 60 is disposed on the first surface 21 of the module substrate 20. A first recessed portion 81 and a second recessed portion 82 are provided in the resin layer 60 toward the module substrate 20 from an upper surface of the resin layer 60. The semiconductor element 30 is accommodated in the first recessed portion 81, and the electronic component 40 is accommodated in the second recessed portion 82. A side surface of the semiconductor element 30 is in contact with a side surface of the first recessed portion 81 in the entire range in a circumferential direction, and a side surface of the electronic component 40 is in contact with a side surface of the second recessed portion 82 in the entire range in a circumferential direction. Only a part of the side surface of the semiconductor element 30 in a height direction may be in contact with the side surface of the first recessed portion 81 in the entire range or a part of the range in the circumferential direction. In addition, only a part of the side surface of the electronic component 40 in a height direction may be in contact with the side surface of the second recessed portion 82 in the entire range or a part of the range in the circumferential direction.

Each of the plurality of conductor columns 62 is disposed in a through-hole penetrating the resin layer 60 in a thickness direction. Side surfaces of the conductor columns 62 are in contact with the resin layer 60. That is, the resin layer 60 is disposed around the semiconductor element 30, the electronic component 40, and each of the plurality of conductor columns 62, and surrounds the semiconductor element 30, the electronic component 40, and each of the plurality of conductor columns 62 without interruption.

Further, the resin layer 60 is also filled in a space between the wiring layer 31 of the semiconductor element 30 and the module substrate 20 and a space between the cover member 48 of the electronic component 40 and the module substrate 20. The resin layer 60 is not filled in the cavity 70 between the cover member 48 of the electronic component 40 and the piezoelectric layer 41.

For example, a low-dielectric constant material having a relative dielectric constant of four or less is used for the resin layer 60. For example, a thermosetting epoxy resin or the like is used for the resin layer 60.

When the first surface 21 is set as a height reference, an upper surface of the resin layer 60 includes a region, which is higher than heights of upper surfaces of the semiconductor element 30 and the electronic component 40, around each of the semiconductor element 30 and the electronic component 40. In the present specification, an expression “an upper surface of A includes a region, which is higher than an upper surface of B, around B” means that the upper surface of B includes a region that is higher than the upper surface of A in an outer side portion of A in a plan view. It is preferable that the region, which is in an upper surface of the resin layer 60 and is higher than the heights of the upper surfaces of the semiconductor element 30 and the electronic component 40, is disposed to surround the semiconductor element 30 and the electronic component 40. Further, it is more preferable that a region, which is in the upper surface of the resin layer 60 and is higher than the heights of the upper surfaces of the semiconductor element 30 and the electronic component 40, is disposed to separately surround the semiconductor element 30 and the electronic component 40.

In the present specification, a “height” means a height in a case where the first surface 21 is set as a height reference, unless otherwise specified. In FIG. 1B, an upper surface of the semiconductor element 30 is a surface of the first insulating layer 33 opposite to the element formation layer 32 side, and an upper surface of the electronic component 40 is a surface of the second insulating layer 42 opposite to the piezoelectric layer 41 side. In a case where the first insulating layer 33 has a stacked structure consisting of a plurality of insulating layers, a surface, which is on a side opposite to the element formation layer 32 side, of an insulating layer farthest from the element formation layer 32 among a plurality of insulating layers constituting the first insulating layer 33 is the upper surface of the semiconductor element 30.

Likewise, in a case where the second insulating layer 42 has a stacked structure consisting of a plurality of insulating layers, a surface, which is on a side opposite to the side of the piezoelectric layer 41, of an insulating layer farthest from the piezoelectric layer 41 among the plurality of insulating layers constituting the second insulating layer 42 is the upper surface of the electronic component 40.

In a region that overlaps the semiconductor element 30 and the electronic component 40 in a plan view, the resin layer 60 is not disposed at a position that is higher than the upper surfaces of the semiconductor element 30 and the electronic component 40. That is, an upper surface of the first insulating layer 33 of the semiconductor element 30 and an upper surface of the second insulating layer 42 of the electronic component 40 are exposed. In a plan view, a first step difference 67 and a second step difference 68 of the resin layer 60 are formed respectively along edges of the semiconductor element 30 and the electronic component 40 in a plan view.

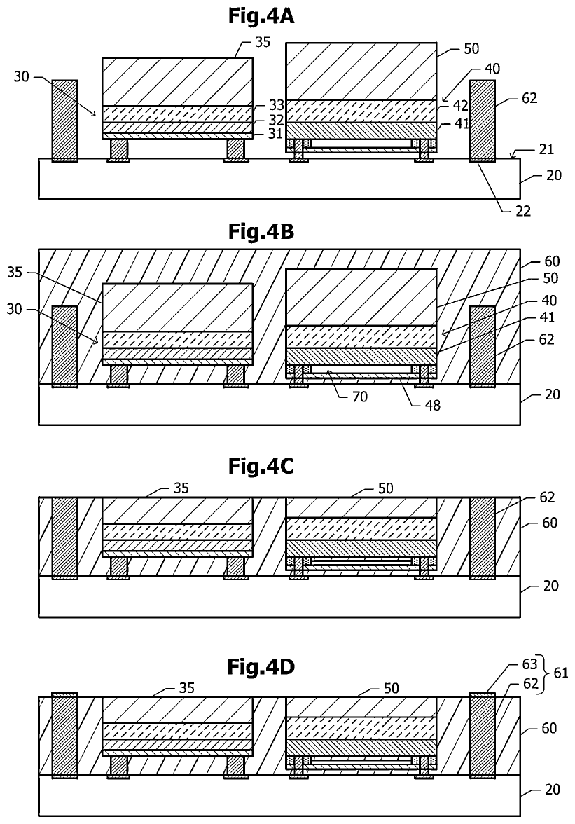

Next, a method of manufacturing an electronic module, according to a first embodiment, will be described with reference to FIG. 4A to FIG. 4D. FIG. 4A to FIG. 4D are cross-sectional views of an electronic module according to the first embodiment in a middle process of manufacturing.

In a process before the semiconductor element 30 and the electronic component 40 are mounted on the module substrate 20, as illustrated in FIG. 4A, the semiconductor element 30 is supported on a temporary support substrate 35 formed of silicon, and the electronic component 40 is supported on a temporary support substrate 50 formed of silicon. Specifically, the first insulating layer 33 of the semiconductor element 30 is bonded to the temporary support substrate 35, and the second insulating layer 42 of the electronic component 40 is bonded to the temporary support substrate 50.

An SOI substrate can be used as the element formation layer 32, the first insulating layer 33, and the temporary support substrate 35. The first insulating layer 33 corresponds to a buried oxide layer (BOX layer) of the SOI substrate. A plurality of transistors are formed in the element formation layer 32, and a plurality of wiring layers are formed in the wiring layer 31.

The conductor columns 62 are respectively formed on a plurality of lands 22 of the first surface 21 of the module substrate 20. The conductor column 62 can be formed, for example, by forming a resist mask having an opening at a position where the conductor column 62 is to be disposed and filling the opening with copper (Cu) by printing or plating the copper. After forming the conductor column 62, the resist mask is removed. Next, the semiconductor element 30 in a state where the temporary support substrate 35 is bonded thereto and the electronic component 40 in a state where the temporary support substrate 50 is bonded thereto are mounted on the module substrate 20.

As illustrated in FIG. 4B, the resin layer 60 is formed on the module substrate 20.

For example, a transfer molded method can be applied to formation of the resin layer 60. Thereby, the semiconductor element 30, the electronic component 40, the temporary support substrates 35 and 50, and the plurality of conductor columns 62 are sealed by the resin layer 60. Resin is not input to the cavity 70 between the piezoelectric layer 41 of the electronic component 40 and the cover member 48.

Next, as illustrated in FIG. 4C, the resin layer 60 is ground or polished to expose the temporary support substrates 35 and 50 and the conductor columns 62. For example, a grinder including a grindstone can be used to grind the resin layer 60. For example, chemical mechanical polishing (CMP) can be used to polish the resin layer 60. The temporary support substrates 35 and 50 before grinding or polishing and heights of upper surfaces of the plurality of conductor columns 62 are not equal to each other. Therefore, the grinding or polishing is performed until the temporary support substrates 35 and 50 and the lowest portions of the plurality of conductor columns 62 are exposed. The temporary support substrates 35 and 50 and the portions of the plurality of conductor columns 62 exposed before the grinding or polishing is finished are ground or polished together with the resin layer 60.

Next, as illustrated in FIG. 4D, the conductor layer 63 is formed on the exposed upper surface of the conductor column 62 by using a plating method. In the process of plating the conductor layer 63, surfaces of the temporary support substrates 35 and 50 are covered with a resist mask such that metal is not plated on the surfaces of the temporary support substrates 35 and 50. The conductor layer 63 is formed by plating, for example, nickel (Ni) and gold (Au) in this order. After plating, the resist mask covering the surfaces of the temporary support substrates 35 and 50 is removed.

Next, the temporary support substrates 35 and 50 are etched and removed under conditions that the temporary support substrates 35 and 50 are more easily etched than the resin layer 60, the first insulating layer 33 of the semiconductor element 30, and the second insulating layer 42 of the electronic component 40. Thereby, as illustrated in FIG. 1B, the first insulating layer 33 of the semiconductor element 30 and the second insulating layer 42 of the electronic component 40 are exposed. It is preferable to use wet etching for etching the temporary support substrates 35 and 50 to reduce damage to the first insulating layer 33 and the second insulating layer 42. For example, an aqueous tetramethylammonium hydroxide solution can be used as an etching solution.

Next, an excellent effect of the first embodiment will be described.

A surface acoustic wave excited in the piezoelectric layer 41 of the electronic component 40 propagates along a surface of the piezoelectric layer 41, but a part of acoustic energy also propagates to the second insulating layer 42. An acoustic constant of the piezoelectric layer 41 has negative temperature characteristics, and an acoustic constant of the second insulating layer 42 has positive temperature characteristics. Therefore, the second insulating layer 42 functions as a temperature characteristic compensation layer that compensates for temperature characteristics of the acoustic constant of the piezoelectric layer 41. By disposing the second insulating layer 42 to be in contact with the piezoelectric layer 41, temperature characteristics of a resonant frequency of an acoustic wave resonator or temperature characteristics of a pass band or stop band of an acoustic wave filter are improved.

In addition, the IDT electrode 43 (FIG. 2A) is disposed in the closed cavity 70 surrounded by the piezoelectric layer 41, the spacer layer 49, and the cover member 48. Accordingly, even when the electronic component 40 is sealed with the resin layer 60, a surface on which a surface acoustic wave of the piezoelectric layer 41 propagates is not in contact with the resin layer 60. Thereby, even after the electronic component 40 is sealed with the resin layer 60, target characteristics of the electronic component 40 are maintained.

In a state where the temporary support substrate 35 formed of silicon is bonded to the semiconductor element 30, harmonic distortion characteristics of the semiconductor element 30 may be problematic due to conductivity or a dielectric property of the temporary support substrate 35. Likewise, even in the electronic component 40, in a state where the temporary support substrate 50 (FIG. 3) is in close contact, harmonic distortion may increase due to conductivity or a dielectric property of the temporary support substrate 50. In the first embodiment, since the temporary support substrates 35 and 50 are removed, harmonic distortion characteristics of the semiconductor element 30 and the electronic component 40 are improved. Further, since the second insulating layer 42 (FIG. 1B) is exposed to the atmosphere, an excellent effect that energy of a surface acoustic wave excited in the piezoelectric layer 41 is confined in the piezoelectric layer 41 and the second insulating layer 42 can be obtained.

Further, in the first embodiment, the semiconductor element 30 and the electronic component 40 are mounted on the common first surface 21 of the common module substrate 20, and the temporary support substrate 35 of the semiconductor element 30 and the temporary support substrate 50 (FIG. 3) of the electronic component 40 are etched and removed at the same time. Therefore, it is possible to reduce manufacturing costs as compared with a method of performing separately a process of removing the temporary support substrate 35 (FIG. 3) of the semiconductor element 30 and a process of removing the temporary support substrate 50 of the electronic component 40.

Next, a modification example of the first embodiment will be described.

In the first embodiment, one semiconductor element 30 and one electronic component 40 are mounted on the module substrate 20, but at least one of a plurality of semiconductor elements 30 and a plurality of electronic components 40 may be mounted. For example, in a case where the electronic module processes high-frequency signals of a plurality of bands, a plurality of electronic components 40 with optimum filter characteristics in each of the plurality of bands may be mounted on the module substrate 20.

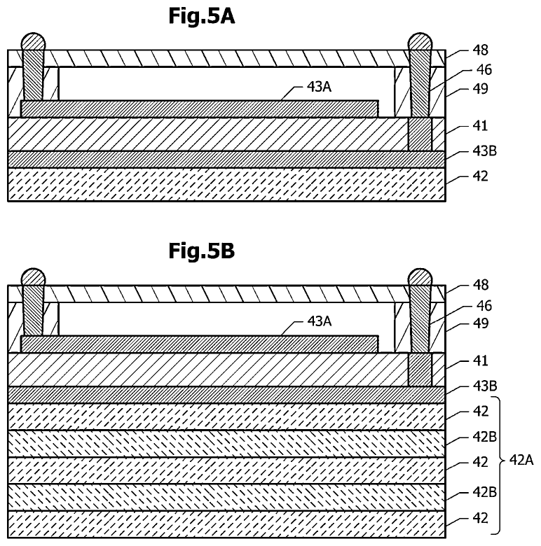

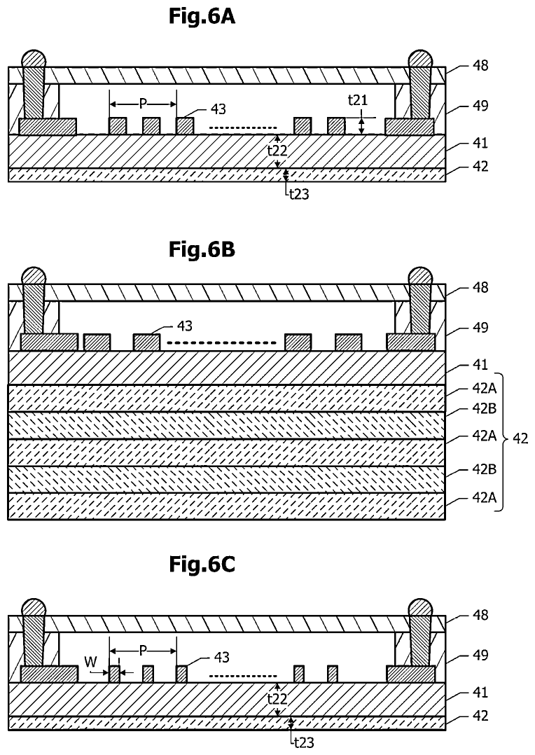

Next, various modification examples of the first embodiment will be described with reference to FIG. 5A to FIG. 6C. In the first embodiment, a resonator or a filter using a surface acoustic wave is adopted as the electronic component 40, but an acoustic wave resonator or an acoustic wave filter having another configuration may be adopted. FIG. 5A to FIG. 6C are cross-sectional views of an electronic component 40 mounted in an electronic module, according to the modification examples of the first embodiment.

In the modification example illustrated in FIG. 5A, electrodes 43A and 43B of a flat-plate shape are disposed on both surfaces of the piezoelectric layer 41 to be overlapped with each other in a plan view.

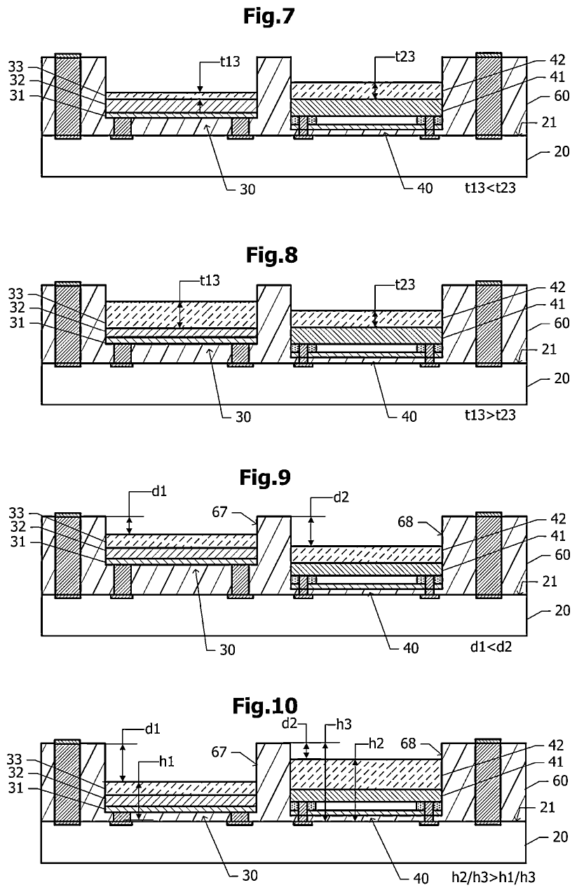

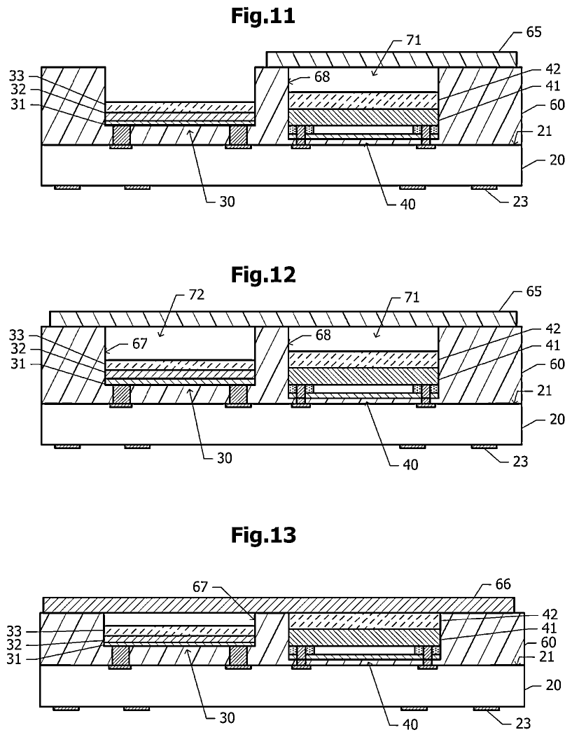

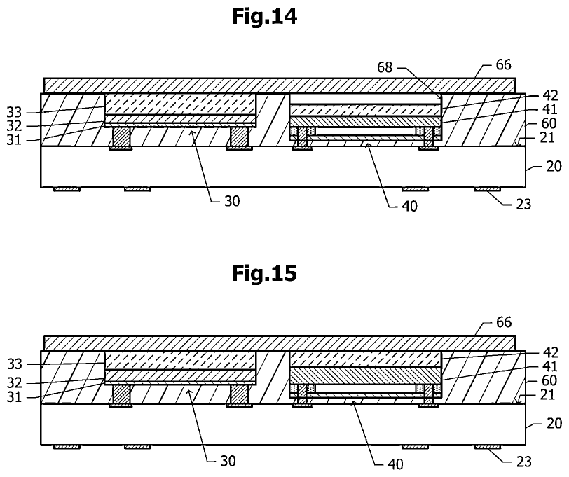

The one electrode 43A is disposed in the cavity 70 between the piezoelectric layer 41 and the cover member 48, and the other electrode 43B is disposed between the piezoelectric layer 41 and the second insulating layer 42. The electronic component 40 according to the present modification example constitutes an acoustic wave resonator using a bulk wave. The electronic component 40 according to the modification example illustrated in FIG. 5A is mounted on the module substrate 20 in an aspect in which the atmosphere is in contact with the second insulating layer 42 as illustrated in FIG. 1B, FIG. 7, FIG. 8, FIG. 9, FIG. 10, FIG. 11, FIG. 14, and the like.

In the modification example illustrated in FIG. 5B, as in the modification example illustrated in FIG. 4A, the electrodes 43A and 43B of a flat-plate shape are disposed on both surfaces of the piezoelectric layer 41 to be overlapped with each other in a plan view. An acoustic reflection film 42A is stacked on the electrode 43B of a flat-plate shape. The acoustic reflection film 42A has a structure in which the second insulating layer 42 (low acoustic impedance layer) formed of a material with relatively small acoustic impedance and a high acoustic impedance layer 42B formed of a material with relatively high acoustic impedance are alternately disposed. The second insulating layer 42 is disposed in a position farthest from the piezoelectric layer 41 in a view from the piezoelectric layer 41. Silicon oxide, silicon nitride, or the like is used for the second insulating layer 42. A metal material such as W or Mo is used for the high acoustic impedance layer 42B. The second insulating layer 42 that functions as a low acoustic impedance layer and the high acoustic impedance layer 42B may each be disposed in a single layer or more.

In the modification example illustrated in FIG. 6A, a plate wave is generated in the piezoelectric layer 41 by the IDT electrode 43 formed on a surface of the piezoelectric layer 41. A piezoelectric material and a crystal axis direction of the piezoelectric layer 41 are optimized for excitation of the plate wave. Further, the thickness t22 of the piezoelectric layer 41, the thickness t23 of the second insulating layer 42, the thickness t21 of the IDT electrode 43, and the period P of an electrode finger of the IDT electrode 43 are also optimized for the excitation of the plate wave. A material of the piezoelectric layer 41 includes, for example, a piezoelectric single crystal such as LiTaO3 or LiNbO3, and piezoelectric ceramics. A material of the second insulating layer 42 includes, for example, silicon oxide, silicon nitride, aluminum nitride, tantalum pentoxide, and so on. The electronic component 40 according to the modification example illustrated in FIG. 6A is mounted on the module substrate 20 in an aspect in which the atmosphere is in contact with the second insulating layer 42 as illustrated in FIG. 1B, FIG. 7, FIG. 8, FIG. 9, FIG. 10, FIG. 11, FIG. 14, and the like.

In the modification example illustrated in FIG. 6B, the IDT electrode 43 is disposed on one surface of the piezoelectric layer 41, and an acoustic reflection film 42A is bonded to the other surface thereof. The acoustic reflection film 42A has the same stacked structure as the acoustic reflection film 42A illustrated in FIG. 5B. For example, the second insulating layer 42 that acts as a low acoustic impedance layer is formed of silicon oxide, and the high acoustic impedance layer 42B is formed of aluminum nitride. A plate wave is excited in the piezoelectric layer 41 by a high-frequency signal supplied to the IDT electrode 43. The plate wave propagating from the piezoelectric layer 41 to the acoustic reflection film 42A is reflected by a lower surface of the second insulating layer 42.

In the modification example illustrated in FIG. 6C, the period P of an electrode finger of the IDT electrode 43 is less than the period P of the electrode finger of the IDT electrode 43 in the modification example illustrated in FIG. 6A. Further, the width W of each electrode fingers of the IDT electrodes 43 is less than ¼ of the period P of the electrode finger.

As in the first embodiment illustrated in FIG. 2A or the modification examples of the first embodiment illustrated in FIG. 5A to FIG. 6C, an acoustic wave resonator or an acoustic wave filter using a surface acoustic wave, a bulk wave, a plate wave, or other acoustic waves may be adopted as the electronic component 40. A piezoelectric material, a crystal axis method, and the thickness t22 of the piezoelectric layer 41, and the thickness t23 of the second insulating layer 42 may be optimized depending on the type of acoustic waves to be excited, wavelengths of the acoustic waves, and the like.

### Second Embodiment

Next, an electronic module according to a second embodiment will be described with reference to FIG. 7. Herein, the common configuration of the electronic module according to the first embodiment described with reference to FIG. 1A to FIG. 4D will not be described.

FIG. 7 is a cross-sectional view of the electronic module according to the second embodiment. In the first embodiment (FIG. 1B), a size relationship between a thickness t13 (FIG. 7) of the first insulating layer 33 of the semiconductor element 30 and the thickness t23 (FIGS. 2A and 2B) of the second insulating layer 42 of the electronic component 40 is not described. In the electronic module according to the second embodiment, a thickness t23 of a second insulating layer 42 of an electronic component 40 is greater than a thickness t13 of a first insulating layer 33 of a semiconductor element 30. In a case where there is a variation in an in-plane direction in each of the thicknesses of the first insulating layer 33 and the thickness of the second insulating layer 42, a thickness of the thickest portion of the first insulating layer 33 may be adopted as the thickness t13, and a thickness of the thickest portion of the second insulating layer 42 may be adopted as the thickness t23.

Next, an excellent effect of the second embodiment will be described.

The second insulating layer 42 of the electronic component 40 having a function of an acoustic wave resonator or an acoustic wave filter has a function of improving temperature dependence characteristics of a resonant frequency. When etching is performed until the first insulating layer 33 of the semiconductor element 30 is exposed in a process of etching temporary support substrates 35 and 50 from the state illustrated in FIG. 4D, a part of the second insulating layer 42 of the electronic component 40 can be etched and removed to be thinned. When the second insulating layer 42 is excessively thinned, an effect of improving the temperature dependence characteristics of the resonant frequency cannot be obtained.

The temporary support substrates 35 and 50 are etched and removed, the first insulating layer 33 and the second insulating layer 42 are exposed, and then over-etching is generally performed for a predetermined time. By obtaining a sufficient etching margin by adopting a configuration in which the thickness t23 of the second insulating layer 42 is greater than a thickness of the first insulating layer 33, the second insulating layer 42 can be prevented from being excessively etched to be too thin during the over-etching. Accordingly, it is possible to suppress reduction of temperature characteristics of a resonant frequency due to excessive thinning of the second insulating layer 42.

In addition, as described with reference to FIG. 4A, a BOX layer of an SOI substrate is used as the first insulating layer 33 of the semiconductor element 30. In general, the BOX layer is formed by thermally oxidizing a surface layer portion of a silicon substrate. In contrast to this, the second insulating layer 42 of the electronic component 40 is formed by sputtering or the like to obtain a desired thickness. Film quality of a silicon oxide film formed by sputtering is worse than film quality of the silicon oxide film formed by thermal oxidation. Accordingly, etching resistance of the second insulating layer 42 under an etching condition for etching and removing the temporary support substrates 35 and 50 (FIG. 4C) is less than etching resistance of the first insulating layer 33.

By providing a configuration in which the thickness t23 of the second insulating layer 42 after etching the temporary support substrates 35 and 50 is greater than the thickness t13 of the first insulating layer 33, it is possible to suppress a reduction in yield due to excessive etching of the second insulating layer 42 even in a situation where the etching resistance of the second insulating layer 42 is low.

### Third Embodiment

Next, an electronic module according to a third embodiment will be described with reference to FIG. 8. Herein, the common configuration of the electronic module according to the second embodiment described with reference to FIG. 7 will not be described.

FIG. 8 is a cross-sectional view of the electronic module according to the third embodiment. In the second embodiment (FIG. 7), the thickness t23 of the second insulating layer 42 of the electronic component 40 is greater than the thickness t13 of the first insulating layer 33 of the semiconductor element 30. In contrast to this, in the third embodiment, a thickness t13 of a first insulating layer 33 of a semiconductor element 30 is greater than a thickness t23 of a second insulating layer 42 of an electronic component 40. In a case where there is a variation in an in-plane direction in each of the thicknesses of the first insulating layer 33 and the thickness of the second insulating layer 42, a thickness of the thickest portion of the first insulating layer 33 may be adopted as the thickness t13, and a thickness of the thickest portion of the second insulating layer 42 may be adopted as the thickness t23.

Next, excellent effects of the third embodiment will be described.

In the electronic component 40, it is preferable to control the thickness t23 of the second insulating layer 42 in high accuracy to improve temperature dependence characteristics of a resonant frequency of an acoustic wave resonator. In contrast to this, the thickness t13 of the first insulating layer 33 of the semiconductor element 30 hardly influences characteristics of the semiconductor element 30. Accordingly, there is no need to increase control accuracy of the thickness t13 of the first insulating layer 33.

In order to control the thickness t23 of the second insulating layer 42 in high accuracy, it is preferable to set an over-etching amount based on a point in time when a temporary support substrate 50 is completely removed and the second insulating layer 42 is exposed in an etching process of removing the temporary support substrates 35 and 50 (FIG. 3). However, it is not preferable that a part of the temporary support substrate 35 remains on the first insulating layer 33 after the over-etching.

When the thickness t13 of the first insulating layer 33 is greater than the thickness t23 of the second insulating layer 42, the over-etching amount can be set based on a point in time when the second insulating layer 42 is exposed. Thereby, it is possible to increase controllability of the thickness t23 of the second insulating layer 42 of the electronic component 40 and to suppress occurrence of etching residues of the temporary support substrate 35 on the first insulating layer 33 of the semiconductor element 30.

### Fourth Embodiment

Next, an electronic module according to a fourth embodiment will be described with reference to FIG. 9. Herein, the common configuration of the electronic module according to the first embodiment described with reference to FIG. 1A to FIG. 4D will not be described.

FIG. 9 is a cross-sectional view of the electronic module according to the fourth embodiment. In the first embodiment (FIG. 1B), a size relationship between a depth of a first step difference 67 and a depth of a second step difference 68 is not described. In the electronic module according to the fourth embodiment, a depth d2 of the second step difference 68 is greater than a depth d1 of the first step difference 67. For example, in the embodiment illustrated in FIG. 9, the depth d2 of the second step difference 68 is greater than the depth d1 of the first step difference 67 by decreasing a height of a bump for mounting an electronic component 40 on a module substrate 20 compared to a height of a bump for mounting a semiconductor element 30 on the module substrate 20. In a case where there is a variation in a circumferential direction in a depth of each of the first step difference 67 and the second step difference 68, a depth at a deepest portion of the first step difference 67 may be adopted as the depth d1, and a depth at a deepest portion of the second step difference 68 may be adopted as the depth d2.

Next, excellent effects of the fourth embodiment will be described.

When another member or a foreign material comes into contact with an exposed surface of a second insulating layer 42 of the electronic component 40, the foreign material or the like in contact with the exposed surface influences propagation of an acoustic wave excited in a piezoelectric layer 41. As a result, frequency characteristics of the electronic component 40 are changed. When the depth d2 of the second step difference 68 is greater than the depth d1 of the first step difference 67, a foreign material or the like is less likely to come into contact with the second insulating layer 42. Thereby, a change in frequency characteristics of the electronic component 40 can be suppressed. Even when a foreign material or the like comes into contact with a first insulating layer 33 of the semiconductor element 30, characteristics of the semiconductor element 30 are not influenced.

### Fifth Embodiment

Next, an electronic module according to a fifth embodiment will be described with reference to FIG. 10. Herein, the common configuration of the electronic module according to the fourth embodiment described with reference to FIG. 9 will not be described.

FIG. 10 is a cross-sectional view of the electronic module according to the fifth embodiment. In the fifth embodiment, a depth d2 of a second step difference 68 along an edge of an electronic component 40 is less than a depth d1 of a first step difference 67 along an edge of a semiconductor element 30. A height of a first insulating layer 33 up to an upper surface thereof when a first surface 21 of a module substrate 20 is set as a height reference is denoted by h1, a height of a second insulating layer 42 up to an upper surface thereof is denoted by h2, and a height of a resin layer 60 up to an upper surface thereof is denoted by h3. In other words, in the fifth embodiment, a ratio of the height h2 to the height h3 is greater than a ratio of the height h1 to the height h3.

Next, excellent effects of the fifth embodiment will be described.

When the resin layer 60 thermally expands, the semiconductor element 30 and the electronic component 40 are deformed due to influence of the resin layer 60. In a case where the ratio of the height h2 to the height h3 is greater than the ratio of the height h1 to the height h3, when the resin layer 60 thermally expands, the resin layer 60 between the semiconductor element 30 and the electronic component 40 is mainly displaced toward the semiconductor element 30 side. Accordingly, deformation of the electronic component 40 is suppressed. Since the deformation of the electronic component 40 is suppressed, a change in resonant frequency due to the deformation of the electronic component 40 can be suppressed.

### Sixth Embodiment

Next, an electronic module according to a sixth embodiment will be described with reference to FIG. 11. Herein, the common configuration of the electronic module according to the first embodiment described with reference to FIG. 1A to FIG. 4D will not be described.

FIG. 11 is a cross-sectional view of the electronic module according to the sixth embodiment. In the first embodiment (FIG. 1A), an outer coupling terminal 61 is exposed on an upper surface of a resin layer 60. In contrast to this, in the sixth embodiment, a plurality of outer coupling terminals 23 are provided on a surface of a module substrate 20 opposite to a first surface 21. The plurality of outer coupling terminals 23 are respectively coupled to a semiconductor element 30 and an electronic component 40 through a wiring structure (not illustrated) in the module substrate 20.

In the first embodiment (FIG. 1A), the second insulating layer 42 of the electronic component 40 is exposed to an outer space. In contrast to this, in the sixth embodiment, a lid 65 including an electronic component 40 is attached in a plan view. The lid 65 is adhered to a top surface of a resin layer 60, and a closed cavity 71 is formed between the second insulating layer 42 of the electronic component 40 and the lid 65. For example, an adhesive tape, a thermal welding film, or so on can be used as the lid 65.

Next, advantageous effects of the sixth embodiment will be described.

In the sixth embodiment, the lid 65 is disposed to be separated from the second insulating layer 42 of the electronic component 40 by the cavity 71, the second insulating layer 42 is less likely to come into contact with other members or foreign materials. Accordingly, a change in frequency characteristics of the electronic component 40 due to a contact of the second insulating layer 42 with a foreign material or the like can be suppressed.

Next, an electronic module according to a modification example of the sixth embodiment will be described with reference to FIG. 12. FIG. 12 is a cross-sectional view of the electronic module according to the modification example of the sixth embodiment.

In the sixth embodiment of implementation (FIG. 11), the lid 65 is disposed to include the electronic component 40 in a plan view, and the semiconductor element 30 does not overlap the lid 65.

In contrast to this, in the modification example illustrated in FIG. 12, a semiconductor element 30 is also included in the lid 65 in a plan view, and a closed cavity 72 is formed between a first insulating layer 33 and the lid 65. The lid 65 is continuous from a region overlapping the semiconductor element 30 in a plan view to a region overlapping an electronic component 40.

Also in the present modification example, a change in frequency characteristics of the electronic component 40 can be suppressed as in the sixth embodiment. In addition, even in a case where the semiconductor element 30 and the electronic component 40 are disposed to be close to each other, an edge of the lid 65 is not required to be aligned between the semiconductor element 30 and the electronic component 40, and thus, an attachment work of the lid 65 is easily performed.

### Seventh Embodiment

Next, an electronic module according to a seventh embodiment will be described with reference to FIG. 13. Herein, the common configuration of the electronic module according to the first embodiment described with reference to FIG. 1A to FIG. 4D will not be described.

FIG. 13 is a cross-sectional view of the electronic module according to the seventh embodiment. In the first embodiment (FIG. 1B), the second step difference 68 of the resin layer 60 is formed along an edge of the electronic component 40 in a plan view. In contrast to this, in the seventh embodiment, a height of an upper surface of a resin layer 60 around an electronic component 40 is equal to a height of an upper surface of a second insulating layer 42 of the electronic component 40. For example, the upper surface of the resin layer 60 includes a region, which has the same height as an upper surface of the electronic component 40, around the electronic component 40. Due to a variation and the like in a manufacturing process, the upper surface of the electronic component 40 and the upper surface of the resin layer 60 around the electronic component 40 are not necessarily on the same plane, and a minute step difference may be formed at a boundary between both surfaces. A configuration of “heights of two surfaces are equal to each other” includes a configuration in which there is a difference in height to the extent that may occur due to a variation in a manufacturing process. For example, in a case where an absolute value of a height of a step difference that occurs at a boundary between two surfaces when measured by a stylus surface roughness meter is 10 μm or less, it can be said that the heights of the two surfaces are equal to each other. A height of an upper surface of a first insulating layer 33 of a semiconductor element 30 is less than a height of an upper surface of the resin layer 60, and a first step difference 67 is formed.

In a state where the resin layer 60 illustrated in FIG. 4B is not ground or polished, a height of an upper surface of the second insulating layer 42 is greater than a height of an upper surface of a first insulating layer 33. A structure of a module substrate 20 according to the seventh embodiment is obtained by performing grinding or polishing until the second insulating layer 42 is exposed in a process of grinding or polishing the resin layer 60.

A lid member 66 of a plate shape formed of an insulating material is provided on the upper surface of the second insulating layer 42 and the upper surface of the resin layer 60. For example, a silicon nitride substrate can be used as the lid member 66. The lid member 66 is adhered or bonded to the upper surface of the second insulating layer 42 and the upper surface of the resin layer 60 by, for example, metal bonding, bonding using an adhesive, direct bonding, or the like. For example, a member of a dome shape, a member having unevenness on an upper surface thereof, or so on may be used as the lid member 66.

Next, excellent effects of the seventh embodiment will be described.

In the seventh embodiment, the lid member 66 is bonded to the second insulating layer 42 of the electronic component 40, and thus, other members or foreign materials do not come into contact with the second insulating layer 42. Accordingly, a change in frequency characteristics of the electronic component 40 due to a contact of a foreign material or the like with the second insulating layer 42 is suppressed. Even when a foreign material or the like comes into contact with a surface of an outer side portion of the lid member 66, the influence on propagation of an excited surface acoustic wave is reduced.

Since a thickness, an acoustic constant, and the like of the lid member 66 are known, the electronic component 40 may be designed under a condition that the lid member 66 is bonded to the second insulating layer 42. In order to confine acoustic energy in the piezoelectric layer 41 and the second insulating layer 42, it is preferable to use a material with acoustic velocity that is faster in the lid member 66 than in the second insulating layer 42 as a material of the lid member 66.

### Eighth Embodiment

Next, an electronic module according to an eighth embodiment will be described with reference to FIG. 14. Herein, the common configuration of the electronic module according to the seventh embodiment described with reference to FIG. 13 will not be described.

FIG. 14 is a cross-sectional view of an electronic module according to an eighth embodiment. In the seventh embodiment (FIG. 13), the height of the upper surface of the resin layer 60 around the electronic component 40 is equal to the height of the upper surface of the second insulating layer 42 of the electronic component 40. In contrast to this, in the eighth embodiment, a height of an upper surface of a resin layer 60 around a semiconductor element 30 is equal to a height of an upper surface of a first insulating layer 33 of the semiconductor element 30. For example, the upper surface of the resin layer 60 includes a region, which has the same height as an upper surface of the semiconductor element 30, around the semiconductor element 30. A height of an upper surface of the second insulating layer 42 of the electronic component 40 is less than the height of an upper surface of the resin layer 60, and a second step difference 68 is formed.

In a state where the resin layer 60 illustrated in FIG. 4B is not ground or polished, the height of the upper surface of the first insulating layer 33 is greater than the height of the upper surface of the second insulating layer 42. A structure of the electronic module according to the eighth embodiment is obtained by performing the grinding or polishing until the first insulating layer 33 is exposed in a process of grinding or polishing the resin layer 60. A lid member 66 formed of an insulating material is provided on (for example, adhered or bonded to) the upper surface of the first insulating layer 33 and the upper surface of the resin layer 60.

Next, excellent effects of the eighth embodiment will be described.

Heat generated in an element formation layer 32 of the semiconductor element 30 is dissipated to an outer space through the first insulating layer 33 and the lid member 66. Accordingly, a heat dissipation property from the semiconductor element 30 can be increased. In order to obtain a sufficient effect of increasing the heat dissipation property, it is preferable to use a material with a higher thermal conductivity than thermal conductivity of the resin layer 60 as a material of the lid member 66. A silicon nitride substrate, or a resin plate or resin film with higher thermal conductivity than thermal conductivity of the resin layer 60 can be used as the lid member 66.

Further, since the lid member 66 has the same function as the lid 65 (FIG. 11) of the electronic module according to the sixth embodiment, a change in frequency characteristics of the electronic component 40 due to a contact of a foreign material or the like with the second insulating layer 42 can be suppressed.

### Ninth Embodiment

Next, an electronic module according to a ninth embodiment will be described with reference to FIG. 15. Herein, the common configuration of the electronic module according to the seventh embodiment described with reference to FIG. 13 will not be described.

FIG. 15 is a cross-sectional view of an electronic module according to a ninth embodiment. In the ninth embodiment, heights of an upper surface of a first insulating layer 33 and an upper surface of a second insulating layer 42 are equal to a height of an upper surface of a resin layer 60 around each of the semiconductor element 30 and the electronic component 40. A lid member 66 is provided on (for example, adhered or bonded to) the upper surface of the first insulating layer 33, the upper surface of the second insulating layer 42, and the upper surface of the resin layer 60.

Next, excellent effects of the ninth embodiment will be described.

In the ninth embodiment, as in the eighth embodiment (FIG. 14), a heat dissipation property from the semiconductor element 30 can be increased. Further, as in the seventh embodiment (FIG. 13), a change in frequency characteristics of the electronic component 40 due to a contact of a foreign material or the like with the second insulating layer 42 is suppressed.

Each of the above-described embodiments is an example, and it goes without saying that partial substitutions or combinations of the configurations illustrated in different embodiments can be made. The same operation and effect according to the same configuration of a plurality of embodiments will not be sequentially referred to for each embodiment. Further, the present disclosure is not limited to the above-described embodiments. For example, it is obvious to those skilled in the art that various changes, improvements, combinations, and the like can be made.

What is claimed is:

1. An electronic module comprising:
a module substrate;
a semiconductor element in which a wiring layer, an element formation layer, and a first insulating layer are stacked and which is mounted on a first surface of the module substrate in a state where the wiring layer faces the module substrate;
an electronic component mounted on the first surface of the module substrate; and
a resin layer on the first surface of the module substrate,
wherein
a first recessed portion and a second recessed portion are in the resin layer, the semiconductor element is accommodated in the first recessed portion, and the electronic component is in the second recessed portion, and
when the first surface is set as a height reference,
an upper surface of the resin layer includes a region, which is higher than or equal to heights of an upper surface of the semiconductor element and an upper surface of the electronic component, around the semiconductor element and the electronic component.

2. The electronic module according to claim 1, wherein
the electronic component includes a piezoelectric layer including a piezoelectric material, and an electrode that excites an acoustic wave in the piezoelectric layer.

3. The electronic module according to claim 1, wherein
the electronic component includes a second insulating layer in an uppermost layer, and the second insulating layer is thicker than the first insulating layer.

4. The electronic module according to claim 1, wherein
the electronic component includes a second insulating layer in an uppermost layer, and the first insulating layer is thicker than the second insulating layer.

5. The electronic module according to claim 1, wherein
when the first surface is set as the height reference, the upper surface of the resin layer includes a region, which is higher than the heights of the upper surface of the semiconductor element and the upper surface of the electronic component, around each of the semiconductor element and the electronic component, and a first step difference and a second step difference of the resin layer are respectively configured along an edge of the semiconductor element and an edge of the electronic component in a plan view, and the second step difference is deeper than the first step difference.

6. The electronic module according to claim 1, wherein
when the first surface is set as the height reference, the upper surface of the resin layer includes a region, which is higher than the heights of the upper surface of the semiconductor element and the upper surface of the electronic component, around each of the semiconductor element and the electronic component, and
a ratio of a height of the upper surface of the electronic component to a height of the upper surface of the resin layer is greater than a ratio of the height of the upper surface of the semiconductor element to the height of the upper surface of the resin layer.

7. The electronic module according to claim 1, wherein
when the first surface is set as the height reference, the upper surface of the resin layer includes a region, which is higher than the heights of the upper surface of the semiconductor element and the upper surface of the electronic component, around each of the semiconductor element and the electronic component, and
the electronic module further includes a lid that includes the electronic component in a plan view, is at a higher position than the upper surface of the electronic component, and is attached to the resin layer.

8. The electronic module according to claim 1, wherein
when the first surface is set as the height reference, a height of the upper surface of the electronic component is equal to a height of the upper surface of the resin layer around the electronic component, and a lid member including an insulating material is on the upper surface of the electronic component and the upper surface of the resin layer.

9. The electronic module according to claim 1, wherein
when the first surface is set as the height reference, a height of an upper surface of the first insulating layer is equal to a height of the upper surface of the resin layer around the semiconductor element, and
a lid member including an insulating material is on the upper surface of the semiconductor element and the upper surface of the resin layer.

10. The electronic module according to claim 1, wherein
when the first surface is set as the height reference, the heights of the upper surface of the semiconductor element and the upper surface of the electronic component are equal to a height of the upper surface of the resin layer around each of the semiconductor element and the electronic component, and
a lid member including an insulating material is on the upper surface of the semiconductor element, the upper surface of the electronic component, and the upper surface of the resin layer.

11. The electronic module according to claim 2, wherein
the electronic component includes a second insulating layer in an uppermost layer, and the second insulating layer is thicker than the first insulating layer.

12. The electronic module according to claim 2, wherein
the electronic component includes a second insulating layer in an uppermost layer, and the first insulating layer is thicker than the second insulating layer.

13. The electronic module according to claim 2, wherein
when the first surface is set as the height reference, the upper surface of the resin layer includes a region, which is higher than the heights of the upper surface of the semiconductor element and the upper surface of the electronic component, around each of the semiconductor element and the electronic component, and a first step difference and a second step difference of the resin layer are respectively configured along an edge of the semiconductor element and an edge of the electronic component in a plan view, and the second step difference is deeper than the first step difference.

14. The electronic module according to claim 3, wherein
when the first surface is set as the height reference, the upper surface of the resin layer includes a region, which is higher than the heights of the upper surface of the semiconductor element and the upper surface of the electronic component, around each of the semiconductor element and the electronic component, and a first step difference and a second step difference of the resin layer are respectively configured along an edge of the semiconductor element and an edge of the electronic component in a plan view, and the second step difference is deeper than the first step difference.

15. The electronic module according to claim 2, wherein
when the first surface is set as the height reference, the upper surface of the resin layer includes a region, which is higher than the heights of the upper surface of the semiconductor element and the upper surface of the electronic component, around each of the semiconductor element and the electronic component, and
a ratio of a height of the upper surface of the electronic component to a height of the upper surface of the resin layer is greater than a ratio of the height of the upper surface of the semiconductor element to the height of the upper surface of the resin layer.

16. The electronic module according to claim 3, wherein
when the first surface is set as the height reference, the upper surface of the resin layer includes a region, which is higher than the heights of the upper surface of the semiconductor element and the upper surface of the electronic component, around each of the semiconductor element and the electronic component, and
a ratio of a height of the upper surface of the electronic component to a height of the upper surface of the resin layer is greater than a ratio of the height of the upper surface of the semiconductor element to the height of the upper surface of the resin layer.

17. The electronic module according to claim 2, wherein
when the first surface is set as the height reference, the upper surface of the resin layer includes a region, which is higher than the heights of the upper surface of the semiconductor element and the upper surface of the electronic component, around each of the semiconductor element and the electronic component, and
the electronic module further includes a lid that includes the electronic component in a plan view, is at a higher position than the upper surface of the electronic component, and is attached to the resin layer.

18. The electronic module according to claim 2, wherein
when the first surface is set as the height reference, a height of the upper surface of the electronic component is equal to a height of the upper surface of the resin layer around the electronic component, and a lid member including an insulating material is on the upper surface of the electronic component and the upper surface of the resin layer.

19. The electronic module according to claim 2, wherein
when the first surface is set as the height reference, a height of an upper surface of the first insulating layer is equal to a height of the upper surface of the resin layer around the semiconductor element, and
a lid member including an insulating material is on the upper surface of the semiconductor element and the upper surface of the resin layer.

20. The electronic module according to claim 2, wherein
when the first surface is set as the height reference, the heights of the upper surface of the semiconductor element and the upper surface of the electronic component are equal to a height of the upper surface of the resin layer around each of the semiconductor element and the electronic component, and
a lid member including an insulating material is on the upper surface of the semiconductor element, the upper surface of the electronic component, and the upper surface of the resin layer.
